(19) United States
(12) Patent Application Publication
(10) Pub. No.: US 2025/0183321 A1
(43) Pub. Date: Jun. 5, 2025

(54) COPPER-GRAPHENE MULTILAYER COMPOSITE COATED COPPER FOIL FOR ANODE CURRENT COLLECTOR

(71) Applicant: GM GLOBAL TECHNOLOGY OPERATIONS LLC, DETROIT, MI (US)

(72) Inventors: Yi Liu, Troy, MI (US); Masoud MohammadPour, Novi, MI (US); Qigui Wang, Rochester Hills, MI (US); Kestutis A. Sonta, Troy, MI (US); Ronald C. Daul, Northville, MI (US)

(21) Appl. No.: 18/529,066

(22) Filed: Dec. 5, 2023

(51) Int. Cl. H01M 4/66; B60L 50/64; C23C 16/26; C23C 28/00; C25D 3/38; C25D 5/54; C25D 7/06; H01M 4/02; H01M 4/04; H01M 50/105; H01M 50/54

(52) U.S. Cl. CPC H01M 4/667; B60L 50/64; C23C 16/26; C23C 28/32; C23C 28/34; C25D 3/38; C25D 5/54; C25D 7/0642; H01M 4/0428; H01M 4/0452; H01M 4/661; H01M 4/663; H01M 50/105; H01M 50/54; H01M 2004/027

(57) ABSTRACT

Aspects of the disclosure include copper-graphene (Cu-Gr) multilayer composite (CGMC) current collectors and methods of manufacturing the same. An exemplary vehicle includes an electric motor and a battery pack electrically coupled to the electric motor. The battery pack includes a battery cell with a cell pouch having therein a plurality of stacked anode current collectors alternating with a plurality of stacked cathode current collectors, and an active material dispersed within the cell pouch to cover the current collectors. Each of the anode current collectors is a CGMC current collector including a copper foil substrate having a top surface and a bottom surface. The copper foil substrate is pure copper. A graphene layer is directly on at least one of the top surface and the bottom surface of the copper foil substrate and a plated copper layer is directly on the graphene layer.

### INTRODUCTION

The present disclosure relates to battery cell manufacturing, and particularly to copper-graphene (Cu-Gr) multilayer composite (CGMC) coated copper foils for anode current collectors.

Electrodes are widely used in a range of devices that store electrical energy, including primary (non-rechargeable) battery cells, secondary (rechargeable) battery cells, fuel cells, and capacitors. An ideal electrode needs to balance various electrical energy storage characteristics, such as, for example, energy density, power density, maximum charging rate, internal leakage current, equivalent series resistance (ESR), charge-discharge cycle durability, high electrical conductivity, and low tortuosity. Electrodes often incorporate current collectors to supplement or otherwise improve upon these electrical energy storage characteristics. Current collectors can be added to provide a higher specific conductance and can increase the available contact area to minimize the interfacial contact resistance between the electrode and its terminal.

A current collector is typically a sheet of conductive material to which the active electrode material is attached. Aluminum foil, stainless steel, and titanium foil are commonly used as the current collector of an electrode. In some electrode fabrication processes, for example, a film that includes activated carbon powder (i.e., the active electrode material) is attached to a thin aluminum foil using an adhesive layer. To improve the quality of the interfacial bond between the film of active electrode material and the current collector, the combination of the film and the current collector is processed in a pressure laminator, for example, a calender. This process is generally known as calendering. Thus, the fabrication of an electrode typically involves the production of an active electrode material film and the lamination of that film onto a current collector.

### SUMMARY

In one exemplary embodiment a vehicle includes an electric motor and a battery pack electrically coupled to the electric motor. The battery pack includes a battery cell with a cell pouch having therein a plurality of stacked anode current collectors alternating with a plurality of stacked cathode current collectors, and an active material dispersed within the cell pouch to cover the current collectors. Each of the anode current collectors is a copper-graphene (Cu-Gr) multilayer composite (CGMC) current collector including a copper foil substrate having a top surface and a bottom surface. The copper foil substrate is pure copper. A graphene layer is directly on at least one of the top surface and the bottom surface of the copper foil substrate and a plated copper layer is directly on the graphene layer.

In addition to one or more of the features described herein, in some embodiments, the anode current collectors further include a first stack of a plurality of graphene layers alternating with a plurality of plated copper layers on the top surface of the copper foil substrate and a second stack of a plurality of graphene layers alternating with a plurality of plated copper layers on the bottom surface of the copper foil substrate.

In some embodiments, the first stack of the plurality of graphene layers alternating with the plurality of plated copper layers includes at least three graphene layers and at least three plated copper layers.

In some embodiments, each graphene layer has a first thickness and each plated copper layer has a second thickness greater than the first thickness. In some embodiments, the first thickness of each of the graphene layers is less than 1 nanometer. In some embodiments, the second thickness of each of the plated copper layers is between 1 nanometer and 40 nanometers. In some embodiments, the second thickness of each of the plated copper layers is substantially equal.

In another exemplary embodiment a CGMC current collector includes a copper foil substrate having a top surface and a bottom surface. The copper foil substrate is pure copper. A graphene layer is directly on at least one of the top surface and the bottom surface of the copper foil substrate and a plated copper layer is directly on the graphene layer.

In some embodiments, the anode current collector further include a first stack of a plurality of graphene layers alternating with a plurality of plated copper layers on the top surface of the copper foil substrate and a second stack of a plurality of graphene layers alternating with a plurality of plated copper layers on the bottom surface of the copper foil substrate.

In some embodiments, the first stack of the plurality of graphene layers alternating with the plurality of plated copper layers includes at least three graphene layers and at least three plated copper layers.

In some embodiments, each graphene layer has a first thickness and each plated copper layer has a second thickness greater than the first thickness. In some embodiments, the first thickness of each of the graphene layers is less than 1 nanometer. In some embodiments, the second thickness of each of the plated copper layers is between 1 nanometer and 40 nanometers. In some embodiments, the second thickness of each of the plated copper layers is substantially equal.

In yet another exemplary embodiment a roll-to-roll manufacturing process for CGMC current collectors can include providing a copper foil substrate having a top surface and a bottom surface. The copper foil substrate is a pure copper foil substrate. The method can include forming a graphene layer directly on at least one of the top surface and the bottom surface of the copper foil substrate and depositing a plated copper layer directly on the graphene layer.

In some embodiments, forming the graphene layer includes subjecting the copper foil substrate to a furnace unit at a furnace temperature of 500 to 1000 degrees Celsius. In some embodiments, the furnace unit is configured to leverage a chemical vapor deposition (CVD) deposition process to deposit the graphene layer onto the copper foil substrate. In some embodiments, the graphene layer is deposited using the CVD deposition process in a high vacuum chamber.

In some embodiments, depositing the plated copper layer includes subjecting the copper foil substrate coated with the graphene layer to a plating unit configured with an anode, a cathode, and a copper source. In some embodiments, the plated copper layer is plated in an environmental controlled high vacuum chamber without breaking vacuum from the furnace unit.

In some embodiments, the furnace unit and the plating unit are repeated as desired to form a first stack of a plurality of graphene layers alternating with a plurality of plated copper layers on the top surface of the copper foil substrate and a second stack of a plurality of graphene layers alternating with a plurality of plated copper layers on the bottom surface of the copper foil substrate.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings.

FIG. 1 is a vehicle configured in accordance with one or more embodiments;

FIG. 2A is an example battery cell in accordance with one or more embodiments;

FIG. 2B is a detailed view of the example battery cell shown in FIG. 2A in accordance with one or more embodiments;

FIG. 2C is a detailed view of one of the anode current collectors shown in FIG. 2B in accordance with one or more embodiments;

FIG. 3A is an example roll-to-roll manufacturing process for copper-graphene (Cu-Gr) multilayer composite (CGMC) coated copper foils in accordance with one or more embodiments;

FIG. 3B is a view of a copper foil substrate at a source unit of the roll-to-roll manufacturing process shown in FIG. 3A in accordance with one or more embodiments;

FIG. 3C is a view of the copper foil substrate after depositing a graphene layer at a furnace unit of the roll-to-roll manufacturing process shown in FIG. 3A in accordance with one or more embodiments;

FIG. 3D is a view of the copper foil substrate after depositing a plated copper layer at a plating unit of the roll-to-roll manufacturing process shown in FIG. 3A in accordance with one or more embodiments;

FIG. 3E is a view of the copper foil substrate after repeating the furnace unit and the plating unit of the roll-to-roll manufacturing process shown in FIG. 3A in accordance with one or more embodiments; and

FIG. 4 is a flowchart in accordance with one or more embodiments.

### DETAILED DESCRIPTION

The following description is merely exemplary in nature and is not intended to limit the present disclosure, its application or uses. It should be understood that throughout the drawings, corresponding reference numerals indicate like or corresponding parts and features.

Electrodes often incorporate current collectors to supplement or otherwise improve upon the electrical energy storage characteristics of a final integrated device (e.g., a battery). A current collector typically includes a sheet of conductive material (e.g., aluminum foil) to which an active electrode material is attached. An energy storage system such as a battery cell or pouch can include a number of stacked anode current collectors and cathode current collectors, an active material(s) dispersed or otherwise situated on the current collectors, and a sufficient number of separators to prevent shorts between the anode current collectors and cathode current collectors.

Copper is frequently chosen as the material for anode current collectors due to a number of desirable properties. One of the key advantages of copper is its relatively high electrical conductivity, which facilitates efficient electron transport within an electrode, providing high performance and enabling rapid charge/discharge cycles. Copper also provides excellent thermal conductivity, aiding in the effective dissipation of heat generated during battery operation, an essential feature for maintaining the stability and longevity of a battery cell, particularly in high-power applications.

A demand for energy storage systems offering higher energy densities, faster charging, and extended operational lifespans, driven in part by the proliferation of electric vehicles, imposes significant challenges on the materials used in battery cell components, and particularly on the current collectors. Copper, commonly selected for its superior conductivity and thermal properties, faces intensified scrutiny in this context. Research and development efforts are continuously directed toward identifying novel materials and manufacturing techniques that can meet escalating demands on battery cells and other energy storage systems.

This disclosure introduces a new copper-graphene (Cu-Gr) multilayer composite (CGMC) coated copper foil anode current collector and methods of manufacturing the same. Rather than relying on pure copper alone, anode current collectors described herein include a number of graphene and plated copper layers formed on an underlying copper foil. In some embodiments, an arbitrarily repeatable roll-to-roll graphene deposition and copper plating process is used to build up any number of alternating graphene and plated copper layers onto the copper foil. The result is a CGMC coated copper foil having an electric conductivity that is higher than 120 percent IACS (the conductivity of annealed copper at 20 Celsius per the International Annealed Copper Standard) and a final device, such as a lithium battery, having improved electron transport, enhanced heat dissipation, and increased capacity as compared to devices having current collectors made of pure copper alone.

Leveraging CGMC coated copper foils for anode current collectors manufactured in accordance with one or more embodiments offers several technical advantages over prior current collector specifications. Notably, the manufacturing process described herein can be used to produce electrodes and current collectors having any number of desired graphene and plate copper levels, subject only to design requirements, in a manner that is natively compatible with both pouch and cylindrical battery cell designs. Other advantages are possible. For example, the copper plating process described herein can be implemented within a continuous roll-to-roll process within an environment controlled vacuum chamber to greatly improve high-volume manufacturability (scaling) over what is possible using other techniques, such as electron beam deposition (EBD).

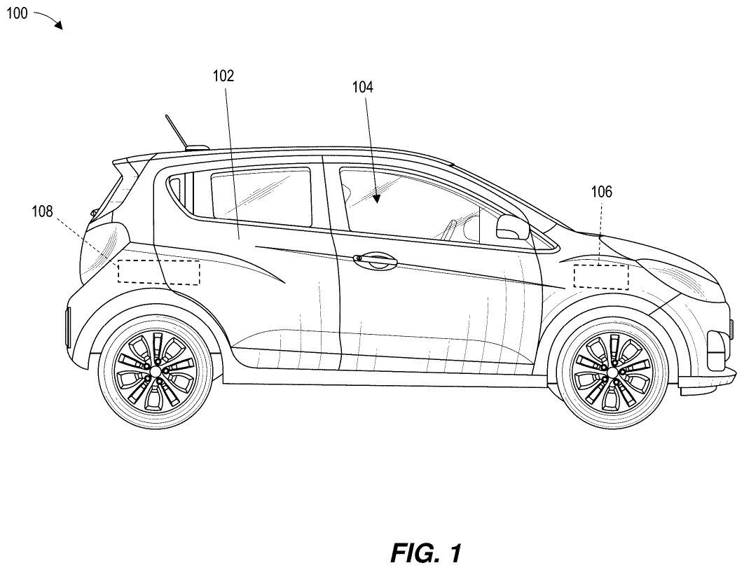

A vehicle, in accordance with an exemplary embodiment, is indicated generally at 100 in FIG. 1. Vehicle 100 is shown in the form of an automobile having a body 102. Body 102 includes a passenger compartment 104 within which are arranged a steering wheel, front seats, and rear passenger seats (not separately indicated). Within the body 102 are arranged a number of components, including, for example, an electric motor 106 (shown by projection under the front hood). The electric motor 106 is shown for ease of illustration and discussion only. It should be understood that the configuration, location, size, arrangement, etc., of the electric motor 106 is not meant to be particularly limited, and all such configurations (including multi-motor configurations) are within the contemplated scope of this disclosure.

The electric motor 106 is powered via a battery pack 108 (shown by projection near the rear of the vehicle 100). The battery pack 108 is shown for ease of illustration and discussion only. It should be understood that the configuration, location, size, arrangement, etc., of the battery pack 108 is not meant to be particularly limited, and all such configurations (including split configurations) are within the contemplated scope of this disclosure. Moreover, while the present disclosure is discussed primarily in the context of a battery pack 108 configured for the electric motor 106 of the vehicle 100, aspects described herein can be similarly incorporated within any system (vehicle, building, or otherwise) having an energy storage system(s) (e.g., one or more battery packs or modules), and all such configurations and applications are within the contemplated scope of this disclosure.

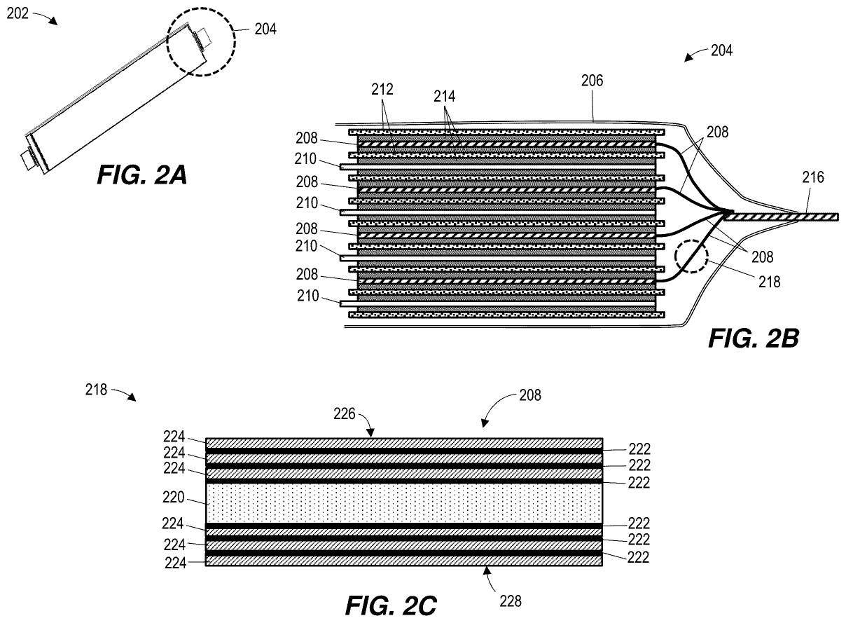

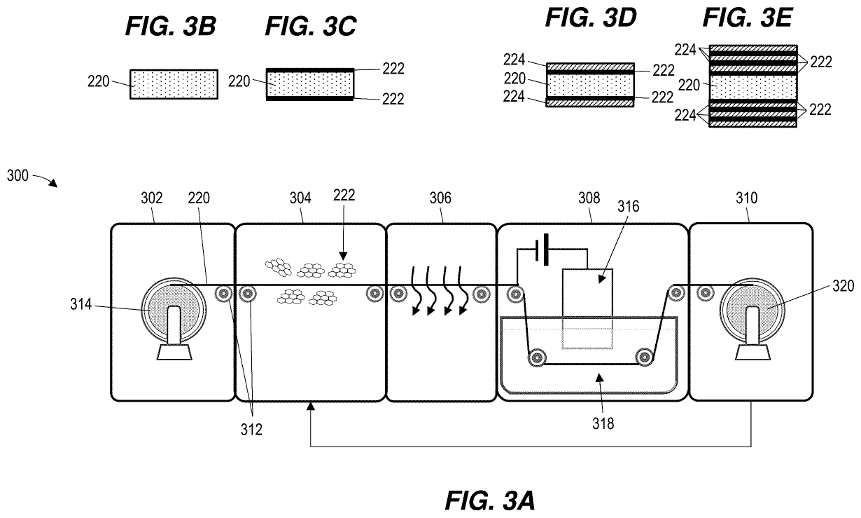

As will be detailed herein, the battery pack 108 includes one or more battery cells and/or battery pouches having one or more CGMC coated copper foil anode current collectors. An example CGMC coated copper foil anode current collector is shown in FIG. 2C. An example manufacturing process for CGMC coated copper foils is shown in FIG. 3A.

FIG. 2A illustrates an example battery cell 202 in accordance with one or more embodiments. The battery cell 202 can be incorporated as one of a number of battery cells in a battery pack (e.g., the battery pack 108 in FIG. 1). FIG. 2B illustrates a detailed view 204 of the example battery cell 202 shown in FIG. 2A in accordance with one or more embodiments. As shown in FIG. 2B, the battery cell 202 includes a cell pouch 206 having therein a number of stacked anode current collectors 208 and cathode current collectors 210. In some embodiments, the anode current collectors 208 and cathode current collectors 210 alternate within the cell pouch 206. The battery cell 202 further includes separators 212 positioned between the anode current collectors 208 and the cathode current collectors 210 and an active material 214 dispersed within the cell pouch 206 to cover the anode current collectors 208 and the cathode current collectors 210. The number of anode current collectors 208, cathode current collectors 210, and separators 212, and the amount of active material 214, is selected only for ease of discussion and convenience. It should be understood that the battery cell 202 can include any number of layers (e.g., anode and cathode layers) and a corresponding number of separators and any amount of active material as desired, and all such configurations are within the contemplated scope of this disclosure.

The anode current collectors 208 and cathode current collectors 210 can be made of sheets or foils of conductive metal. For example, the cathode current collectors 210 can be made of aluminum foil, stainless steel, and/or titanium foil, to which the active material 214 is attached. Other materials are possible, such as, for example, semimetals (e.g., tin, graphite) and alloys of the metals and/or semimetals thereof. In some embodiments, the cathode current collectors 210 are made of aluminum foil. The anode current collectors 208 can include CGMC coated copper foils and are discussed in greater detail with respect to FIG. 2C.

The separators 212 can include dielectric materials such as, for example, polyethylene (PE), polypropylene (PP), polyethylene terephthalate (PET), and composites thereof, although other dielectrics are within the contemplated scope of this disclosure.

The active material 214 is not meant to be particularly limited, but can include, for example, various cathode or anode materials (depending on the requirements of a specific application), such as, for example, activated carbon powder, nickel manganese cobalt oxide (NMC), lithium iron phosphate (LFP), nickel cobalt aluminum oxide (NCA), nickel cobalt manganese aluminum oxide (NCMA), lithium manganese iron phosphate (LMFP), lithium manganese rich (LMR), lithium manganese oxide (LMO), graphite, silicon, silicon-graphite composites, tin, tin oxide (SnO₂), lithium titanate (Li₄Ti₅O₁₂, LTO), sulfur and lithium-sulfur (Li—S) composites, lithium metal (Li), and/or lithium alloys such as lithium-antimony (Li—Sb), lithium-aluminum (Li—Al), and lithium-germanium (Li—Ge).

In some embodiments, the anode current collectors 208 collectively terminate at a lead tab 216 (also referred to as a busbar). In some embodiments, the lead tab 216 is made of a same or similar material as the anode current collectors 208. For example, in some embodiments, the lead tab 216 is a copper foil. In some embodiments, the lead tab 216 is a CGMC coated copper foil. While not separately shown, the cathode current collectors 210 can also collectively terminate at a (separate) lead tab and/or busbar as well (omitted for clarity).

As discussed previously, the anode current collectors 208 can include CGMC coated copper foils. FIG. 2C illustrates a detailed view 218 of one of the anode current collectors 208 shown in FIG. 2B in accordance with one or more embodiments. As shown in FIG. 2C, the anode current collectors 208 can include a copper foil substrate 220.

In some embodiments, an alternating stack of graphene layers 222 and plated copper layers 224 are formed over a top surface 226 and/or a bottom surface 228 of the copper foil substrate 220. An example manufacturing process for forming the alternating stack of graphene layers 222 and plated copper layers 224 is discussed in greater detail with respect to FIG. 3A.

In some embodiments, each of the graphene layers 222 is formed to a thickness of less than or equal to 1 nanometer. In some embodiments, the graphene layers 222 can be formed to a thickness of a few angstroms, for example, 1, 2, 3, 4, 5, 6, 7, 8, 9, 10 angstroms. In some embodiments, the graphene layers 222 can be formed to a thickness between 1 and 4 angstroms.

In some embodiments, each of the plated copper layers 224 is formed to a thickness between 1 nanometer and a few tens of nanometers. For example, the plated copper layers 224 can be formed to a thickness of 1 to 40 nanometers, 1 to 20 nanometers, 1 to 10 nanometers, and 1 to 5 nanometers. In some embodiments, each of the plated copper layers 224 is formed to a substantially same thickness (that is, a same thickness within tooling limits, e.g., within 1%, 3%, 5% of a nominal thickness).

The anode current collectors 208 can include a copper foil substrate 220 and any number of alternating graphene layers 222 and plated copper layers 224. For example, the anode current collector 208 shown in FIG. 2C includes a copper foil substrate 220 and alternating stacks of three graphene layers 222 and three plated copper layers 224. Other configurations having a different number of alternating graphene layers 222 and plated copper layers 224 (e.g., 1 layer each, 2, 4, 5, 6, 8, 10, 15, 20, 50, etc.) are possible and all such configurations are within the contemplated scope of this disclosure. Moreover, the anode current collector 208 shown in FIG. 2C depicts a double-sided configuration (that is, alternating graphene layers 222 and plated copper layers 224 are formed over both the top surface 226 and the bottom surface 228 of the copper foil substrate 220) for convenience. Other configurations (e.g., single-sided configurations from either, but not both, of the top surface 226 and the bottom surface 228) are possible and all such configurations are within the contemplated scope of this disclosure.

FIG. 3A illustrates an example roll-to-roll manufacturing process 300 for CGMC coated copper foils in accordance with one or more embodiments. As shown in FIG. 3A, the roll-to-roll manufacturing process 300 includes a source unit 302, a furnace unit 304, a dryer unit 306, a plating unit 308, and a collection unit 310, sequenced as shown. In some embodiments, a sequence of positioning rollers 312 directs the copper foil substrate 220 along the roll-to-roll manufacturing process 300 (that is, from unit to unit in the overall sequence).

In some embodiments, the roll-to-roll manufacturing process 300 begins at the source unit 302, where a copper foil substrate 220 (refer to FIG. 2C) is placed on or otherwise sourced to an input roller 314. In some embodiments, the copper foil substrate 220 is a copper foil that is wound into a roll that is placed onto the input roller 314. In some embodiments, the copper foil substrate 220 is fed to the roll-to-roll manufacturing process 300 (e.g., the input roller 314) as a continuous copper foil sheet (not separately shown).

In some embodiments, the positioning rollers 312 move or otherwise direct the copper foil substrate 220 from the source unit 302 to the furnace unit 304. FIG. 3B depicts a view of the copper foil substrate 220 as it leaves the source unit 302.

In some embodiments, the furnace unit 304 leverages a chemical vapor deposition (CVD) process to deposit a graphene layer(s) 222 onto the copper foil substrate 220. In some embodiments, the graphene layers 222 are deposited using CVD deposition in a high vacuum chamber. As used herein, a “high vacuum” chamber refers to a controlled environment chamber where air and other gases are removed to create a vacuum in the range of 10⁻³ to 10⁻⁸ torr. For example, a high vacuum chamber can operate at a pressure below 10⁻⁶ torr. In some embodiments, the graphene layers 222 are deposited using CVD deposition at a furnace temperature of 500 to 1000 degrees Celsius. In some embodiments, the graphene layers 222 are deposited using a CVD deposition chemistry that includes methane, hydrogen gas, and Argon. In some embodiments, the graphene layers 222 are deposited to a thickness of less than or equal to 1 nanometer. In some embodiments, the graphene layers 222 can be formed to a thickness between 1 and 4 angstroms.

In some embodiments, the positioning rollers 312 move or otherwise direct the copper foil substrate 220 from the furnace unit 304 to the dryer unit 306. FIG. 3C is a view of the copper foil substrate 220 after depositing the graphene layers 222, prior to moving to the dryer unit 306.

In some embodiments, the dryer unit 306 dries and/or cools the copper foil substrate 220 to fix the deposited graphene layers 222 onto a surface of the copper foil substrate 220. In some embodiments, cooling and drying occurs in a transition vacuum chamber. In some embodiments, the transition vacuum chamber is at a same vacuum (e.g., a high vacuum) as the furnace unit 304. In some embodiments, the graphene layers 222 are cooled at a temperature of less than 300 degrees Celsius. While not meant to be particularly limited, cooling can be achieved through methods like forced air cooling, liquid cooling, and/or contact cooling using, for example, pre-cooled surfaces. In some embodiments, the graphene layers 222 are dried through techniques such as vacuum drying, heat-assisted drying, and/or via the use of inert carrier gases. Drying can be used to achieve desired material characteristics and to evaporate residual liquids, such as solvents or liquids used for synthesis and transfer of the graphene layers 222 to the copper foil substrate 220.

In some embodiments, the positioning rollers 312 move or otherwise direct the copper foil substrate 220 from the dryer unit 306 to the plating unit 308.

In some embodiments, the plating unit 308 leverages an anode 316 and a cathode 318 to plate exposed surfaces of the graphene layers 222 with plated copper layers 224. In some embodiments, the anode 316 is a copper source. In some embodiments, the plated copper layers 224 are plated in an environmental controlled high vacuum chamber, making the connection with other vacuum chambers (refer to the furnace unit 304 and the dryer unit 306) straightforward and more robust to vacuum loss or leaks. In some embodiments, the plated copper layers 224 are deposited to a thickness between 1 nanometer and a few tens of nanometers. For example, the plated copper layers 224 can be deposited to a thickness of 1 to 40 nanometers, 1 to 20 nanometers, 1 to 10 nanometers, and 1 to 5 nanometers. In some embodiments, each of the plated copper layers 224 is formed to a substantially same thickness (that is, a same thickness within tooling limits, e.g., within 1%, 3%, 5% of a nominal thickness). FIG. 3D is a view of the copper foil substrate 220 after depositing the plated copper layers 224.

In some embodiments, the positioning rollers 312 move or otherwise direct the copper foil substrate 220 from the plating unit 308 to the collection unit 310.

In some embodiments, the collection unit 310 includes a collection roller 320 (also referred to as a rewind roller) configured to recover the copper foil substrate 220 after forming the graphene layers 222 and the plated copper layers 224. In some embodiments, the collection roller 320 is configured to recover the copper foil substrate 220 after a single pass through the furnace unit 304 and the plating unit 308. In some embodiments, the collection roller 320 is configured to recover the copper foil substrate 220 after multiple passes through the furnace unit 304 and the plating unit 308.

In some embodiments, a reverse-roller scheme is relied upon to enable multiple passes through the furnace unit 304 and the plating unit 308. In this configuration, one or more of the collection roller 320 and/or any combination of the positioning rollers 312 is configured for both forward and backward (reverse) positioning of the copper foil substrate 220. In some embodiments, the collection roller 320 and/or any combination of the positioning rollers 312 are reversed in direction after the copper foil substrate 220 completes the plating unit 308 (that is, after formation of the plated copper layers 224). In some embodiments, the copper foil substrate 220, after completing the plating unit 308, is reversed back into the dryer unit 306 to be cooled and/or dried prior to ultimately being reversed back into the furnace unit 304. Once back in the furnace unit 304, the roll-to-roll manufacturing process 300 can be repeated to form additional graphene and plated copper layers.

In some embodiments, a take-off-and-replace scheme is relied upon to enable multiple passes through the furnace unit 304 and the plating unit 308. In this configuration, the copper foil substrate 220 is collected (via, e.g., a roll wind up) and removed from the collection roller 320 after the copper foil substrate 220 completes the plating unit 308 (that is, after formation of the plated copper layers 224). In some embodiments, the copper foil substrate 220, coated with the graphene layers 222 and plated copper layers 224, is then placed back onto the input roller 314 and the roll-to-roll manufacturing process 300 can be repeated as previously described to form additional graphene layers 222 and plated copper layers 224.

Regardless of the multi-pass method employed, FIG. 3E is a view of the copper foil substrate 220 after repeating the furnace unit 304 and the plating unit 308 of the roll-to-roll manufacturing process 300 shown in FIG. 3A. In particular, FIG. 3E shows the copper foil substrate 220 after repeating the furnace unit 304 and the plating unit 308 three times. It should be understood, however, that the furnace unit 304 and the plating unit 308 can be repeated any number of times (1, 2, 3, 4, 5, 10, 20, etc. times) as desired to create CGMC coated copper foils having any number of graphene and plated copper layers and all such configurations are within the contemplated scope of this disclosure.

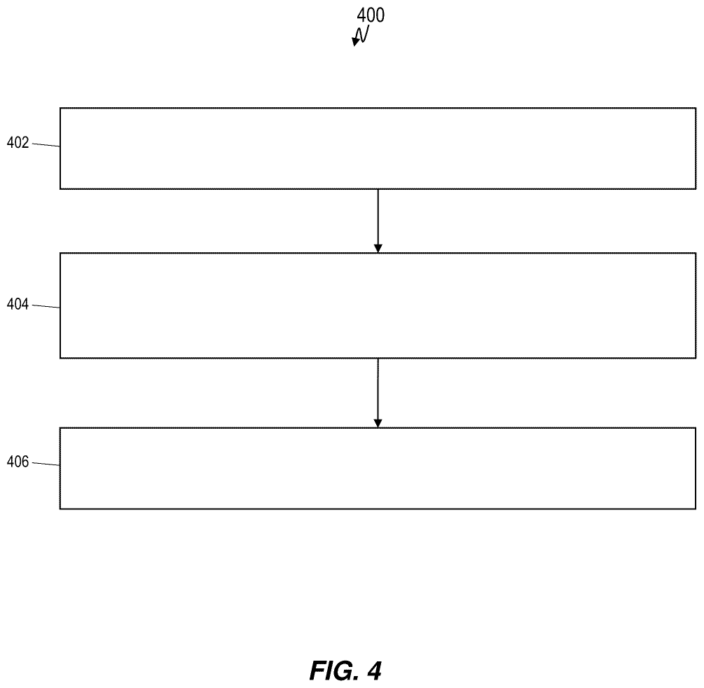

Referring now to FIG. 4, a flowchart 400 for manufacturing CGMC coated copper foils using a roll-to-roll manufacturing process is generally shown according to an embodiment. The flowchart 400 is described in reference to FIGS. 1-3E and may include additional steps not depicted in FIG. 4. Although depicted in a particular order, the blocks depicted in FIG. 4 can be rearranged, subdivided, and/or combined.

At block 402, the method includes providing a copper foil substrate having a top surface and a bottom surface. In some embodiments, the copper foil substrate is a pure copper foil substrate. As used herein, a “pure” copper foil substrate means a substantially pure copper foil less any impurities, where the impurities are less than 3 percent by weight copper.

At block 404, the method includes forming a graphene layer directly on at least one of the top surface and the bottom surface of the copper foil substrate. In some embodiments, forming the graphene layer includes subjecting the copper foil substrate to a furnace unit at a furnace temperature of 500 to 1000 degrees Celsius. The furnace unit is configured to leverage a CVD deposition process to deposit the graphene layer onto the copper foil substrate. In some embodiments, the graphene layer is deposited using the CVD deposition process in a high vacuum chamber.

At block 406, the method includes depositing a plated copper layer directly on the graphene layer. In some embodiments, depositing the plated copper layer includes subjecting the copper foil substrate coated with the graphene layer to a plating unit configured with an anode, a cathode, and a copper source. In some embodiments, the plated copper layer is plated in an environmental controlled high vacuum chamber without breaking vacuum from the furnace unit.

In some embodiments, each graphene layer has a first thickness and each plated copper layer has a second thickness greater than the first thickness. In some embodiments, the first thickness of each of the graphene layers is less than 1 nanometer. In some embodiments, the second thickness of each of the plated copper layers is between 1 nanometer and 40 nanometers. In some embodiments, the second thickness of each of the plated copper layers is substantially equal (e.g., within tooling limits).

In some embodiments, the method includes repeating the furnace unit and the plating unit as many times as desired to form a first stack of a plurality of graphene layers alternating with a plurality of plated copper layers on the top surface of the copper foil substrate and a second stack of a plurality of graphene layers alternating with a plurality of plated copper layers on the bottom surface of the copper foil substrate.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A vehicle comprising:
an electric motor; and
a battery pack electrically coupled to the electric motor, the battery pack comprising a battery cell, the battery cell comprising a cell pouch having therein a plurality of stacked anode current collectors alternating with a plurality of stacked cathode current collectors, and an active material dispersed within the cell pouch to cover the plurality of stacked anode current collectors and the plurality of stacked cathode current collectors;
wherein each of the stacked anode current collectors comprises a copper-graphene (Cu-Gr) multilayer composite (CGMC) current collector comprising:
a copper foil substrate having a top surface and a bottom surface, the copper foil substrate comprising pure copper;
a graphene layer directly on at least one of the top surface and the bottom surface of the copper foil substrate; and
a plated copper layer directly on the graphene layer.

2. The vehicle of claim 1, the stacked anode current collectors further comprising a first stack of a plurality of graphene layers alternating with a plurality of plated copper layers on the top surface of the copper foil substrate and a second stack of a plurality of graphene layers alternating with a plurality of plated copper layers on the bottom surface of the copper foil substrate.

3. The vehicle of claim 2, wherein the first stack of the plurality of graphene layers alternating with the plurality of plated copper layers comprises at least three graphene layers and at least three plated copper layers.

4. The vehicle of claim 2, wherein each graphene layer has a first thickness and each plated copper layer has a second thickness greater than the first thickness.

5. The vehicle of claim 4, wherein the first thickness of each of the plurality of graphene layers is less than 1 nanometer.

6. The vehicle of claim 4, wherein the second thickness of each of the plurality of plated copper layers is between 1 nanometer and 40 nanometers.

7. The vehicle of claim 4, wherein the second thickness of each of the plurality of plated copper layers is substantially equal.

8. A copper-graphene (Cu-Gr) multilayer composite (CGMC) current collector comprising:
a copper foil substrate having a top surface and a bottom surface, the copper foil substrate comprising pure copper;
a graphene layer directly on at least one of the top surface and the bottom surface of the copper foil substrate; and
a plated copper layer directly on the graphene layer.

9. The current collector of claim 8, further comprising a first stack of a plurality of graphene layers alternating with a plurality of plated copper layers on the top surface of the copper foil substrate and a second stack of a plurality of graphene layers alternating with a plurality of plated copper layers on the bottom surface of the copper foil substrate.

10. The current collector of claim 9, wherein the first stack of the plurality of graphene layers alternating with the plurality of plated copper layers comprises at least three graphene layers and at least three plated copper layers.

11. The current collector of claim 9, wherein each graphene layer has a first thickness and each plated copper layer has a second thickness greater than the first thickness.

12. The current collector of claim 11, wherein the first thickness of each of plurality of the graphene layers is less than 1 nanometer.

13. The current collector of claim 11, wherein the second thickness of each of the plurality of plated copper layers is between 1 nanometer and 40 nanometers.

14. The current collector of claim 11, wherein the second thickness of each of the plurality of plated copper layers is substantially equal.

15. A roll-to-roll manufacturing process for copper-graphene (Cu-Gr) multilayer composite (CGMC) current collectors, the process comprising:
providing a copper foil substrate having a top surface and a bottom surface, the copper foil substrate comprising pure copper;
forming a graphene layer directly on at least one of the top surface and the bottom surface of the copper foil substrate; and
depositing a plated copper layer directly on the graphene layer.

16. The process of claim 15, wherein forming the graphene layer comprises subjecting the copper foil substrate to a furnace unit at a furnace temperature of 500 to 1000 degrees Celsius, the furnace unit configured to leverage a chemical vapor deposition (CVD) deposition process to deposit the graphene layer onto the copper foil substrate.

17. The process of claim 15, wherein the graphene layer is deposited using the CVD deposition process in a high vacuum chamber.

18. The process of claim 16, wherein depositing the plated copper layer comprises subjecting the copper foil substrate coated with the graphene layer to a plating unit configured with an anode, a cathode, and a copper source.

19. The process of claim 18, wherein the plated copper layer is plated in an environmental controlled high vacuum chamber without breaking vacuum from the furnace unit.

20. The process of claim 19, further comprising repeating the furnace unit and the plating unit to form a first stack of a plurality of graphene layers alternating with a plurality of plated copper layers on the top surface of the copper foil substrate and a second stack of a plurality of graphene layers alternating with a plurality of plated copper layers on the bottom surface of the copper foil substrate.
